(19) United States
(12) Patent Application Publication
(10) Pub. No.: US 2021/0183936 A1
(43) Pub. Date: Jun. 17, 2021

(54) IMAGE SENSOR

(71) Applicant: Eagle Vision Tech Limited, Hong Kong (HK)

(72) Inventor: Sywe-Neng Lee, Taipei (TW)

(73) Assignee: Eagle Vision Tech Limited, Hong Kong (HK)

(21) Appl. No.: 16/884,011

(22) Filed: May 26, 2020

(30) Foreign Application Priority Data
Dec. 11, 2019 (TW) 108145336

(51) Int. Cl. H01L 27/146

(52) U.S. Cl. CPC H01L 27/14627; H01L 27/14621; H01L 27/14609; H01L 27/14636; H01L 27/14629

(57) ABSTRACT

An image sensor including a semiconductor substrate, micro-lenses, color filters, an interconnection structure and a reflecting layer is provided. The semiconductor substrate has a first surface and a second surface opposite to each other and includes sensing pixels each including photosensitive elements. The micro-lenses are located over the first surface of the semiconductor substrate. The color filters are located between the semiconductor substrate and the micro-lenses. The interconnection structure is located over the second surface of the semiconductor substrate and is electrically coupled to the photosensitive elements. The reflecting layer is located between the interconnection structure and the photosensitive elements and is configured to reflect all or a portion of light passing through the photosensitive elements back to the photosensitive elements.

The interconnection structure includes circuit layers stacked alternately, and the reflecting layer is located at a same level as one of the circuit layers closest to the semiconductor substrate.

### CROSS-REFERENCE TO RELATED APPLICATION

This application claims the priority benefit of Taiwan application serial no. 108145336, filed on Dec. 11, 2019. The entirety of the above-mentioned patent application is hereby incorporated by reference herein and made a part of this specification.

### BACKGROUND

### Technical Field

The disclosure relates to a sensing device, and in particular, to an image sensor.

### Description of Related Art

Compared with a charge coupled device (CCD), a complementary metal-oxide-semiconductor image sensor (CMOS image sensor, CIS) has the advantages of low operating voltage, low power consumption, high operating efficiency, capability of random access and the like, and may also be integrated into the existing semiconductor technology so as to be manufactured in batches, so the application range is very wide.

Pixel photosensitive elements of the CIS are mainly composed of PN diodes, and the intensity of image signals generated after light sensing depends on an area of a photosensitive region and the intensity of the incident light. For the back-side illuminated (BSI) CIS widely used in the current market, transistors, capacitors and metal circuit layers thereof are all built at bottom layers of the pixel photosensitive elements. Therefore, sizes of the pixel photosensitive regions of the BSI-CIS are almost equal to sizes of the pixels so as to greatly improve the photosensitivity.

### SUMMARY

The invention is directed to an image sensor capable of effectively improving photosensitivity.

The image sensor of the invention includes a semiconductor substrate, a plurality of micro-lenses, a plurality of color filters, an interconnection structure and a reflecting layer. The semiconductor substrate has a first surface and a second surface opposite to each other. The semiconductor substrate includes a plurality of sensing pixels arranged in an array, and each of the plurality of sensing pixels includes a plurality of photosensitive elements. The plurality of micro-lenses are located over the first surface of the semiconductor substrate. The plurality of color filters are located between the semiconductor substrate and the plurality of micro-lenses. The interconnection structure is located over the second surface of the semiconductor substrate and is electrically coupled to the plurality of photosensitive elements. The reflecting layer is located between the interconnection structure and the plurality of photosensitive elements and is configured to reflect all or a portion of light passing through the plurality of photosensitive elements back to the plurality of photosensitive elements. The interconnection structure includes a plurality of circuit layers stacked alternately, and the reflecting layer is located at a same level as one of the plurality of circuit layers closest to the semiconductor substrate.

Based on the above, the image sensor according to the embodiments of the invention may enable all or a portion of light passing through the photosensitive elements to be irradiated to the photosensitive elements again by the reflecting layer. Therefore, the light entering the sensor may be collected more efficiently so as to improve the photosensitivity of the image sensor.

To make the features and advantages of the invention clear and easy to understand, the following gives a detailed description of embodiments with reference to accompanying drawings.

### BRIEF DESCRIPTION OF THE DRAWINGS

FIG. 1 is a schematic cross-sectional diagram of an image sensor according to a first embodiment of the invention.

FIG. 2 is a schematic cross-sectional diagram of an image sensor according to a second embodiment of the invention.

### DESCRIPTION OF THE EMBODIMENTS

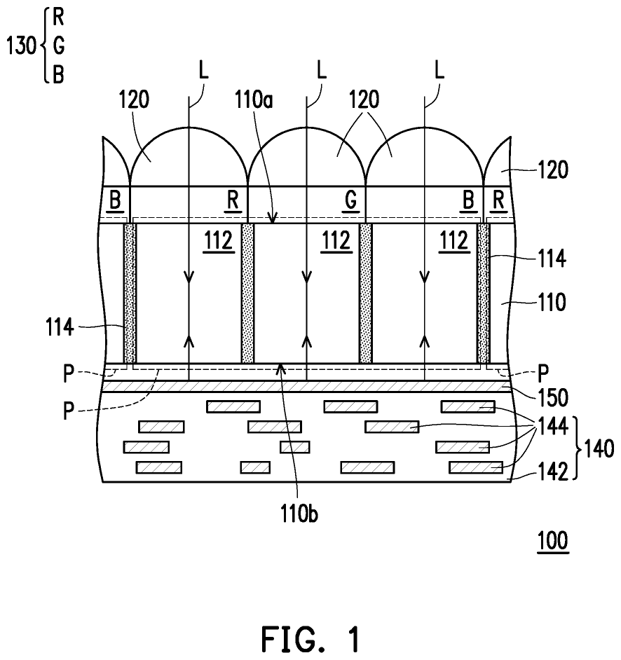

FIG. 1 is a schematic cross-sectional diagram of an image sensor according to a first embodiment of the invention. An image sensor 100 of the present embodiment may be applied to various high-pixel electronic devices (such as cameras, mobile phones and computers) for image shooting, and may achieve full-color image sensing. For example, the image sensor 100 of the present embodiment may be applied to an electronic device with 12 million pixels or 64 million pixels. When the image sensor 100 is applied to a camera of a mobile phone with 64 million pixels, the size of each pixel may be 1.4*1.4 μm² or 0.7*0.7 μm², but the invention is not limited thereto.

Referring to FIG. 1, the image sensor 100 includes a semiconductor substrate 110, a plurality of micro-lenses 120, a plurality of color filters 130, an interconnection structure 140 and a reflecting layer 150. The semiconductor substrate 110 has a first surface 110a and a second surface 110b opposite to each other. The semiconductor substrate 110 includes a plurality of sensing pixels P arranged in an array, and each of the plurality of sensing pixels P includes a plurality of photosensitive elements 112. The plurality of micro-lenses 120 are located over the first surface 110a of the semiconductor substrate 110. The plurality of color filters 130 are located between the semiconductor substrate 110 and the plurality of micro-lenses 120. The interconnection structure 140 is located over the second surface 110b of the semiconductor substrate 110 and is electrically coupled to the plurality of photosensitive elements 112. The reflecting layer 150 is located between the interconnection structure 140 and the plurality of photosensitive elements 112 and is configured to reflect all or a portion of light L passing through the plurality of photosensitive elements 112 back to the plurality of photosensitive elements 112.

Specifically, the image sensor 100 of the present embodiment is a back-side illuminated complementary metal-oxide-semiconductor image sensor (BSI-CIS), the first surface 110a of the semiconductor substrate 110 may be referred to as a back surface, and the second surface 110b of the semiconductor substrate 110 may be referred to as a front surface (or an active surface). The light (or radiation) L enters the back surface (namely the first surface 110a) of the semiconductor substrate 110, and enters the photosensitive elements 112 through the back surface (namely the first surface 110a) to perform an image sensing function. However, a portion of the light L may pass through the photosensitive elements 112 and may not be effectively sensed. Therefore, the image sensor 100 of the present embodiment may enable all or a portion of the light L passing through the photosensitive elements 112 to be irradiated to the photosensitive elements 112 again by the reflecting layer 150. Therefore, the light L entering the image sensor 100 may be collected more efficiently so as to improve the sensing sensitivity of the image sensor 110.

In the present embodiment, the semiconductor substrate 110 may be made of the following materials: a suitable elemental semiconductor, such as crystalline silicon, diamond or germanium; a suitable compound semiconductor, such as gallium arsenide, silicon carbide, indium arsenide or indium phosphide; or a suitable alloy semiconductor, such as silicon germanium carbide, gallium arsenic phosphide or gallium indium phosphide. The semiconductor substrate 110 may be a p-type substrate or an n-type substrate. For example, when the semiconductor substrate 110 is the p-type substrate, the semiconductor substrate 110 may be doped with a p-type doping agent (such as boron), and when the semiconductor substrate 110 is the n-type substrate, the semiconductor substrate 110 may be doped with an n-type doping agent (such as phosphorus or arsenic).

The semiconductor substrate 110 may include a plurality of isolation structures 114 to define a plurality of active regions in the semiconductor substrate 110. The isolation structures 114 extend from the first surface 110a of the semiconductor substrate 110 to the second surface 100b of the semiconductor substrate 110. The plurality of photosensitive elements 112 is respectively formed in the plurality of active regions defined in the semiconductor substrate 110. For example, the isolation structures 114 may include deep trench isolation (DTI) structures to isolate the plurality of photosensitive elements 112 from each other, so that the light signal interference between adjacent photosensitive elements 112 may be significantly reduced. However, in other embodiments, the isolation structures 114 may also include shallow trench isolation (STI) structures, implant isolation structures or other isolation structures. The photosensitive elements 112 may include photo-diodes. The photo-diodes may include at least one p-type doped region, at least one n-type doped region, and a p-n junction formed between the p-type doped region and the n-type doped region. A method for forming the photosensitive elements 112 may be an ion implantation method. Specifically, when the semiconductor substrate 110 is the p-type substrate, the n-type doping agent (such as phosphorus or arsenic) may be doped in the active regions to form an n-type well, and the p-n junction formed in the semiconductor substrate 110 may perform an image sensing function. Similarly, when the semiconductor substrate 110 is the n-type substrate, the p-type doping agent (such as boron) may be doped in the active regions to form a p-type well. When a reversed bias is applied to the p-n junction of the photosensitive elements 112, the p-n junction is sensitive to incident light. At this time, the photosensitive elements 112 are in a floating high impedance state. After being irradiated by light for a period of time, the photosensitive elements 112 may generate a current, and a resulting pressure difference is an image signal. That is, the light received or detected by the photosensitive elements 112 may be converted into a photo-current, and then, an image signal may be generated and output.

Furthermore, the image sensor 100 may also include one or more pixel transistors (not shown in the figure) on the active surface (namely the second surface 110b) of the semiconductor substrate 110. For example, the pixel transistor may include a transfer transistor configured to transfer the charges generated in the photosensitive elements 112 out of the photosensitive elements 112 for reading. Furthermore, the pixel transistor may also include other transistors, such as a source-follower transistor, a row select transistor, a reset transistor, and the like. For the purpose of clarity, the semiconductor elements are not shown in FIG. 1.

The color filters 130 are disposed on the first surface 110a of the semiconductor substrate 110, and each of the plurality of color filters 130 respectively corresponds to each of the plurality of photosensitive elements 112. The color filters 130 allow transmission of the light having a specific wavelength range, and simultaneously block the light having a wavelength exceeding the specific range. For example, the plurality of color filters 130 may include a red light filter R, a green light filter G and a blue light filter B. The red light filter R allows red light to pass through, so that the red light is received by the photosensitive elements 112 located below the red light filter R. The green light filter G allows green light to pass through, so that the green light is received by the photosensitive elements 112 located below the green light filter G. The blue light filter B allows blue light to pass through, so that the blue light is received by the photosensitive elements 112 located below the blue light filter B. The image sensor 100 of the present embodiment is suitable for sensing the light having a light wavelength within a visible light range.

The plurality of micro-lenses 120 is disposed on the plurality of color filters 130, and each of the plurality of micro-lenses 120 respectively corresponds to each of the plurality of color filters 130. The plurality of micro-lenses 120 may form a micro-lens array. The center points of the plurality of micro-lenses 120 are substantially aligned with the center points of the plurality of color filters 130 in a vertical direction respectively. The micro-lenses 120 may be configured to focus the incident light L to the photosensitive elements 112. After the light L is refracted by the micro-lenses 120, the light L may substantially enter the reflecting layer 150 vertically, and the reflecting layer reflects the light L back to the photosensitive elements 112 to improve the light collection efficiency. Because the light L is almost vertically incident, the light L is not reflected to other adjacent photosensitive elements 112 so as to reduce the noise interference.

As shown in FIG. 1, the interconnection structure 140 is disposed on the active surface (namely the second surface 110b) of the semiconductor substrate 110 and is electrically coupled to the photosensitive elements 112, so that signals generated from the photosensitive elements 112 may be transmitted to other elements for processing. In the present embodiment, the interconnection structure 140 includes an interlayer dielectric (ILD) layer 142 and a plurality of circuit layers 144 stacked alternately in the ILD layer 142. The material of the ILD layer 142 includes silicon oxide, silicon nitride, silicon oxynitride, phosphosilicate glass (PSG), borophosphosilicate glass (BPSG), spin-on glass (SOG), fluorinated silica glass (FSG), carbon-doped silicon oxide (such as SiCOH), polyimide, or a combination thereof. The materials of the circuit layers 144 include conductive materials, such as metals. Four or five circuit layers 144 may be disposed, but the invention is not limited thereto. In other embodiments, the interconnection structure 140 may include more or less circuit layers 144. Specifically, one of the plurality of circuit layers 144 closest to the semiconductor substrate 110 may be a metal one layer, and the circuit layers 144 stacked on the metal one layer may be sequentially a metal two layer, a metal three layer, and so on. Taking five circuit layers 144 as an example, one of the plurality of circuit layers 144 closest to the semiconductor substrate 110 may be a metal one layer, and one of the plurality of circuit layers 144 furthest from the semiconductor substrate 110 may be a metal five layer. According to the present embodiment, one of the plurality of circuit layers 144 closest to the semiconductor substrate 110 may be disposed on the metal five layer, one of the plurality of circuit layers 144 furthest from the semiconductor substrate 110 may be disposed on the metal one layer, and so on. In the present embodiment, because the interconnection structure 140 is disposed on the opposite side (namely the second surface 110b) of a light incidence surface (namely the first surface 110a), namely below the photosensitive elements 112, the interconnection structure 140 does not block the light L from irradiating on the photosensitive elements 112.

In the present embodiment, the reflecting layer 150 may be a sheet metal layer, the reflecting layer 150 extends continuously in a direction parallel to the semiconductor substrate 110, and orthographic projections of the plurality of photosensitive elements 112 on the reflecting layer 150 are located within a range of the reflecting layer 150. In other words, viewing from top to bottom, the plurality of photosensitive elements 112 may overlap the reflecting layer 150, so that the light L passing through the photosensitive elements 112 may be reflected by the reflecting layer 150 and irradiated to the photosensitive elements 112 again. In the present embodiment, the reflecting layer 150 may be formed in a same process as one of the plurality of circuit layers 144 closest to the semiconductor substrate 110 (namely the metal one layer). In other words, the reflecting layer 150 may be located at a same level as one of the plurality of circuit layers 144 closest to the semiconductor substrate 110 (namely the metal one layer), and the reflecting layer 150 and the circuit layers 144 may include a same material (such as metal). It should be noted that in order to clearly show the reflecting layer 150, a circuit layer (namely a metal one layer) at the same level as the reflecting layer 150 is not shown.

Because the reflecting layer 150 may be formed together with the circuit layers 144, that is, the existing process may be utilized for manufacturing the reflecting layer 150, additional process steps are not needed, high process compatibility is realized, and no additional cost is increased. Furthermore, because the reflecting layer 150 may be a metal layer, the reflection of the light L on the reflecting layer 150 may be mirror reflection, and the light L is not easy to scattered, the vertically incident light L may be vertically reflected to the photosensitive elements 112 to prevent the light L from being scattered to other adjacent photosensitive elements 112 so as to reduce the noise interference.

In the present embodiment, the reflecting layer 150 is electrically disconnected from the photosensitive elements 112. In an embodiment, the reflecting layer 150 may be coupled to a power voltage (VDD) or a grounding voltage (GND), so that the reflecting layer 150 may serve as signal shielding to reduce signal interference and disturbance between the photosensitive elements 112 and the circuit layers 144. However, in other embodiments, the reflecting layer 150 may also be in electrical floating.

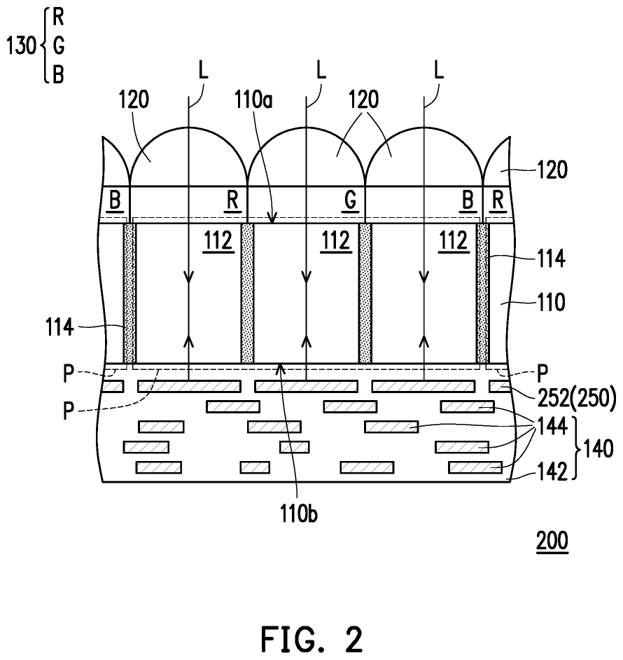

FIG. 2 is a schematic cross-sectional diagram of an image sensor according to a second embodiment of the invention. Referring to FIG. 2, an image sensor 200 of the present embodiment is similar to the image sensor 100 in FIG. 1, so that details thereof are omitted herein. Compared with FIG. 1, a reflecting layer 250 of the image sensor 200 in FIG. 2 may include a plurality of separated reflecting blocks 252, and an orthographic projection of each of a plurality of photosensitive elements 112 on the reflecting layer 250 is respectively located within a range of each of the plurality of reflecting blocks 252. In other words, viewing from top to bottom, one of the plurality of photosensitive elements 112 may overlap one of the plurality of reflecting blocks 252, so that the light L passing through the photosensitive elements 112 may be reflected by the reflecting layer 250 and irradiated to the photosensitive elements 112 again. Furthermore, the reflecting layer 250 may also include a plurality of connecting lines (not shown) connected among the plurality of reflecting blocks 252.

In conclusion, the image sensor according to the embodiments of the invention may enable all or a portion of the light passing through the photosensitive elements to be irradiated to the photosensitive elements again by the reflecting layer. Therefore, the light entering the image sensor may be utilized more efficiently so as to improve the sensing sensitivity of the image sensor.

Although the invention is described with reference to the above embodiments, the embodiments are not intended to limit the invention. A person of ordinary skill in the art may make variations and modifications without departing from the spirit and scope of the invention. Therefore, the protection scope of the invention should be subject to the appended claims.

What is claimed is:

1. An image sensor, comprising:
a semiconductor substrate, comprising a first surface and a second surface opposite to each other, wherein the semiconductor substrate comprises a plurality of sensing pixels arranged in an array, and each of the plurality of sensing pixels comprises a plurality of photosensitive elements;
a plurality of micro-lenses, located over the first surface of the semiconductor substrate;
a plurality of color filters, located between the semiconductor substrate and the plurality of micro-lenses;
an interconnection structure, located over the second surface of the semiconductor substrate and electrically coupled to the plurality of photosensitive elements; and
a reflecting layer, located between the interconnection structure and the plurality of photosensitive elements and configured to reflect all or a portion of light passing through the plurality of photosensitive elements back to the plurality of photosensitive elements, wherein the interconnection structure comprises a plurality of circuit layers stacked alternately, and the reflecting layer is located at a same level as one of the plurality of circuit layers closest to the semiconductor substrate.

2. The image sensor according to claim 1, wherein the reflecting layer is electrically disconnected from the plurality of photosensitive elements.

3. The image sensor according to claim 1, wherein the reflecting layer comprises a metal layer.

4. The image sensor according to claim 1, wherein the reflecting layer is coupled to a power voltage or a grounding voltage.

5. The image sensor according to claim 1, wherein the reflecting layer extends continuously in a direction parallel to the semiconductor substrate, and orthographic projections of the plurality of photosensitive elements on the reflecting layer are located within a range of the reflecting layer.

6. The image sensor according to claim 1, wherein the reflecting layer comprises a plurality of separated reflecting blocks, and an orthographic projection of each of the plurality of photosensitive elements on the reflecting layer is respectively located within a range of each of the plurality of reflecting blocks.

7. The image sensor according to claim 1, wherein the reflecting layer and the plurality of circuit layers comprise a same material.

8. The image sensor according to claim 1, wherein the semiconductor substrate further comprises a plurality of isolation structures, and the plurality of isolation structures isolate the plurality of photosensitive elements from each other.

9. The image sensor according to claim 1, wherein the plurality of color filters comprise a red light filter, a green light filter and a blue light filter.
